(19) United States
(12) Patent Application Publication
(10) Pub. No.: US 2011/0201207 A1
(43) Pub. Date: Aug. 18, 2011

(54) BACKPLANE STRUCTURES FOR SOLUTION PROCESSED ELECTRONIC DEVICES

(75) Inventors: Yaw-Ming A. Tsai, Taichung (TW); Matthew Stainer, Goleta, CA (US)

(73) Assignee: E. I. DU PONT DE NEMOURS AND COMPANY, Wilmington, DE (US)

(21) Appl. No.: 13/077,176

(22) Filed: Mar. 31, 2011

Related U.S. Application Data
(62) Division of application No. 12/237,487, filed on Sep. 25, 2008.
(60) Provisional application No. 60/974,972, filed on Sep. 25, 2007.

(51) Int. Cl. H01L 21/302; G03F 7/20

(52) U.S. Cl. 438/703; 430/311; 257/E21.214

(57) ABSTRACT

There is provided a backplane for an organic electronic device. The backplane has a TFT substrate; a multiplicity of electrode structures; and a bank structure defining a multiplicity of pixel openings on the electrode structures. The bank structure has a height adjacent to the pixel opening, h_{A}, and a height removed from the pixel opening, h_{R}, and h_{A} is significantly less than h_{R}.

### RELATED APPLICATION

This application claims priority under 35 U.S.C. §119(e) from Provisional Application No. 60/974,972 filed Sep. 25, 2007 which is incorporated by reference as if fully set forth herein.

### BACKGROUND INFORMATION

1. Field of the Disclosure

This disclosure relates in general to electronic devices and processes for forming the same. More specifically, it relates to backplane structures and devices formed by solution processing using the backplane structures.

2. Description of the Related Art

Electronic devices, including organic electronic devices, continue to be more extensively used in everyday life. Examples of organic electronic devices include organic light-emitting diodes (“OLEDs”). A variety of deposition techniques can be used in forming layers used in OLEDs. Liquid deposition techniques include printing techniques such as ink-jet printing and continuous nozzle printing.

As the devices become more complex and achieve greater resolution, the use of active matrix circuitry with thin film transistors (“TFTs”) becomes more necessary. However, surfaces of most TFT substrates are not planar. Liquid deposition onto these non-planar surfaces can result in non-uniform films. The non-uniformity may be mitigated by the choice of solvent for the coating formulation and/or by controlling the drying conditions. However, there still exists a need for a TFT substrate design that will result in improved film uniformity.

### SUMMARY

In one embodiment, there is provided a process for forming a backplane for an organic electronic device, the process comprising:

providing a TFT substrate having a multiplicity of electrode structures thereon;

forming a photoresist layer overall;

exposing the photoresist to activating radiation through a gradient mask, the mask having a pattern of transparent areas, opaque areas, and semi-transmissive areas, such that a multiplicity of first areas of the photoresist layer are fully exposed, a multiplicity of second areas of the photoresist layer are partially exposed, and a multiplicity of third areas of the photoresist layer are not exposed;

developing the photoresist layer to form an organic bank structure.

In another embodiment, there is provided an alternative process for forming a backplane for an organic electronic device, the process comprising:

providing a TFT substrate having a multiplicity of electrode structures thereon;

forming an electrically insulating inorganic layer overall

forming a photoresist layer overall;

exposing the photoresist to activating radiation through a gradient mask, the mask having a pattern of transparent areas, opaque areas, and semi-transmissive areas, such that a multiplicity of first areas of the photoresist layer are fully exposed, a multiplicity of second areas of the photoresist layer are partially exposed, and a multiplicity of third areas of the photoresist layer are not exposed;

developing the photoresist layer to form an etching mask;

treating with an etchant to remove portions of the underlying electrically insulating inorganic layer to form an inorganic bank structure.

There is also provided a backplane for an organic electronic device comprising:

a TFT substrate;

a multiplicity of electrode structures;

a bank structure defining a multiplicity of pixel openings on the electrode structures;

wherein, the bank structure has a height adjacent to the pixel opening, h_{A}, and a height removed from the pixel opening, h_{R}, and h_{A} is significantly less than h_{R}.

The foregoing general description and the following detailed description are exemplary and explanatory only and are not restrictive of the scope of the appended claims.

### BRIEF DESCRIPTION OF THE DRAWINGS

Embodiments are illustrated in the accompanying figures to assist in understanding concepts presented in this disclosure.

FIG. 1 includes, as illustration, a schematic diagram of one embodiment of a gradient mask, as described herein.

FIG. 2 includes, as illustration, a schematic diagram of one embodiment of a gradient mask, as described herein.

FIG. 3 includes, as illustration, a schematic diagram of one embodiment of a gradient mask, as described herein.

FIG. 4 includes, as illustration, a schematic diagram of a backplane for an electronic device, as described herein.

FIG. 5 includes, as illustration, a schematic diagram of a backplane for an electronic device, as described herein.

FIG. 6 includes, as illustration, a schematic diagram of a prior art bank structure containing a layer of active organic material.

FIG. 7 includes, as illustration, a schematic diagram of a new bank structure as described herein containing a layer of active organic material.

Skilled artisans will appreciate that objects in the figures are illustrated for simplicity and clarity and have not necessarily been drawn to scale. For example, the dimensions of some of the objects in the figures may be exaggerated relative to other objects to help to improve understanding of embodiments.

### DETAILED DESCRIPTION

Many aspects and embodiments are described throughout the disclosure and are exemplary and not limiting. After reading this specification, skilled will artisans appreciate that other aspects and embodiments are possible without departing from the scope of the invention.

Other features and benefits of any one or more of the embodiments will be apparent from the following detailed description, and from the claims. The detailed description first addresses Definitions and Clarification of Terms followed by a First Embodiment of the Process for Forming a Backplane, a Second Embodiment of the Process for Forming a Backplane, the gradient Mask, the Backplane and the Bank Structure, the Process for Forming an Electronic Device, and finally Examples.

### 1. Definitions and Clarification of Terms

Before addressing details of embodiments described below, some terms are defined or clarified. Definitions include variants, such as inflected forms, of the defined terms.

As used herein, the term “active” when referring to a layer or material refers to a layer or material that electronically facilitates the operation of the device. Examples of active materials include, but are not limited to, materials that conduct, inject, transport, or block a charge, where the charge can be either an electron or a hole. Examples also include a layer or material that has electronic or electro-radiative properties. An active layer material may emit radiation or exhibit a change in concentration of electron-hole pairs when receiving radiation.

The term “active matrix” is intended to mean an array of electronic components and corresponding driver circuits within the array.

The term “backplane” is intended to mean a workpiece on which organic layers can be deposited to form an electronic device.

The term “circuit” is intended to mean a collection of electronic components that collectively, when properly connected and supplied with the proper potential(s), performs a function. A circuit may include an active matrix pixel within an array of a display, a column or row decoder, a column or row array strobe, a sense amplifier, a signal or data driver, or the like.

The term “connected,” with respect to electronic components, circuits, or portions thereof, is intended to mean that two or more electronic components, circuits, or any combination of at least one electronic component and at least one circuit do not have any intervening electronic component lying between them. Parasitic resistance, parasitic capacitance, or both, are not considered electronic components for the purposes of this definition. In one embodiment, electronic components are connected when they are electrically shorted to one another and lie at substantially the same voltage. Note that electronic components can be connected together using fiber optic lines to allow optical signals to be transmitted between such electronic components.

The term “coupled” is intended to mean a connection, linking, or association of two or more electronic components, circuits, systems, or any combination of at least two of: (1) at least one electronic component, (2) at least one circuit, or (3) at least one system in such a way that a signal (e.g., current, voltage, or optical signal) may be transferred from one to another. Non-limiting examples of “coupled” can include direct connections between electronic components, circuits or electronic components with switch(es) (e.g., transistor(s)) connected between them, or the like.

The term “driver circuit” is intended to mean a circuit configured to control the activation of an electronic component, such as an organic electronic component.

The term “electrically continuous” is intended to mean a layer, member, or structure that forms an electrical conduction path without an electrically open circuit.

The term “electrically insulating” is intended to refer to a material, layer, member, or structure having an electrical property such that it substantially prevents any significant current from flowing through such material, layer, member or structure.

The term “electrode” is intended to mean a structure configured to transport carriers. For example, an electrode may be an anode or a cathode. Electrodes may include parts of transistors, capacitors, resistors, inductors, diodes, organic electronic components and power supplies.

The term “electronic component” is intended to mean a lowest level unit of a circuit that performs an electrical function. An electronic component may include a transistor, a diode, a resistor, a capacitor, an inductor, or the like. An electronic component does not include parasitic resistance (e.g., resistance of a wire) or parasitic capacitance (e.g., capacitive coupling between two conductors connected to different electronic components where a capacitor between the conductors is unintended or incidental).

The term “electronic device” is intended to mean a collection of circuits, electronic components, or combinations thereof that collectively, when properly connected and supplied with the proper potential(s), performs a function. An electronic device may include, or be part of, a system. Examples of electronic devices include displays, sensor arrays, computer systems, avionics, automobiles, cellular phones, and many other consumer and industrial electronic products.

The term “layer” is used interchangeably with the term “film” and refers to a coating covering a desired area. The area can be as large as an entire device or as small as a specific functional area such as the actual visual display, or as small as a single sub-pixel. Films can be formed by any conventional deposition technique, including vapor deposition, liquid deposition and thermal transfer. Typical liquid deposition techniques include, but are not limited to, continuous deposition techniques such as spin coating, gravure coating, curtain coating, dip coating, slot-die coating, spray coating, and continuous nozzle coating; and discontinuous deposition techniques such as ink jet printing, gravure printing, and screen printing.

The term “light-transmissive” is used interchangeably with “transparent” and is intended to mean that at least 50% of incident light of a given wavelength is transmitted. In some embodiments, 70% of the light is transmitted.

The term “liquid composition” is intended to mean an organic active material that is dissolved in a liquid medium or media to form a solution, dispersed in a liquid medium or media to form a dispersion, or suspended in a liquid medium or media to form a suspension or an emulsion.

The term “opening” is intended to mean an area characterized by the absence of a particular structure that surrounds the area, as viewed from the perspective of a plan view.

The term “organic electronic device” is intended to mean a device including one or more semiconductor layers or materials. Organic electronic devices include: (1) devices that convert electrical energy into radiation (e.g., a light-emitting diode, light emitting diode display, or diode laser), (2) devices that detect signals through electronics processes (e.g., photodetectors (e.g., photoconductive cells, photoresistors, photoswitches, phototransistors, or phototubes), IR detectors, or biosensors), (3) devices that convert radiation into electrical energy (e.g., a photovoltaic device or solar cell), and (4) devices that include one or more electronic components that include one or more organic semiconductor layers (e.g., a transistor or diode).

The term “overlying,” when used to refer to layers, members or structures within a device, does not necessarily mean that one layer, member or structure is immediately next to or in contact with another layer, member, or structure.

The term “perimeter” is intended to mean a boundary of a layer, member, or structure that, from a plan view, forms a closed planar shape.

The term “photoresist” is intended to mean a photosensitive material that can be formed into a layer. When exposed to activating radiation, at least one physical property and/or chemical property of the photoresist is changed such that the exposed and unexposed areas can be physically differentiated.

The term “structure” is intended to mean one or more patterned layers or members, which by itself or in combination with other patterned layer(s) or member(s), forms a unit that serves an intended purpose. Examples of structures include electrodes, well structures, cathode separators, and the like.

The term “substrate” is intended to mean a base material that can be either rigid or flexible and may be include one or more strata, including layers, of one or more materials, which can include, but are not limited to, glass, polymer, metal or ceramic materials or combinations thereof.

The term “TFT substrate” is intended to mean a substrate including an array of TFTs and/or driving circuitry to make panel function.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

Also, use of “a” or “an” are employed to describe elements and components described herein. This is done merely for convenience and to give a general sense of the scope of the invention. This description should be read to include one or at least one and the singular also includes the plural unless it is obvious that it is meant otherwise.

Group numbers corresponding to columns within the Periodic Table of the elements use the “New Notation” convention as seen in the CRC Handbook of Chemistry and Physics, 81^{st} Edition (2000-2001).

Unless otherwise defined, all technical and scientific terms used herein have the same meaning as commonly understood by one of ordinary skill in the art to which this invention belongs. Although methods and materials similar or equivalent to those described herein can be used in the practice or testing of embodiments of the present invention, suitable methods and materials are described below. All publications, patent applications, patents, and other references mentioned herein are incorporated by reference in their entirety, unless a particular passage is cited. In case of conflict, the present specification, including definitions, will control. In addition, the materials, methods, and examples are illustrative only and not intended to be limiting.

To the extent not described herein, many details regarding specific materials, processing acts, and circuits are conventional and may be found in textbooks and other sources within the organic light-emitting diode display, photodetector, photovoltaic, and semiconductive member arts.

### 2. First Embodiment of the Process for Forming a Backplane

In the first embodiment, the process for forming a backplane for an electronic device comprises:

providing a TFT substrate having a multiplicity of electrode structures thereon;

forming a photoresist layer overall;

exposing the photoresist to activating radiation through a gradient mask, the mask having a pattern of transparent areas, opaque areas, and semi-transmissive areas, such that a multiplicity of first areas of the photoresist layer are fully exposed, a multiplicity of second areas of the photoresist layer are partially exposed, and a multiplicity of third areas of the photoresist layer are not exposed;

developing the photoresist layer to form an organic bank structure.

In an embodiment, the transparency to radiation of each semi-transmissive area is homogeneous, i.e., substantially uniform.

TFT substrates are well known in the electronic arts. The substrate may be a conventional substrate as used in organic electronic device arts. The substrate can be flexible or rigid, organic or inorganic. In some embodiments, the substrate is transparent. In some embodiments, the substrate is glass or a flexible organic film. The TFT array may be located over or within the substrate, as is known. The substrate can have a thickness in the range of about 12 to 2500 microns.

The term “thin-film transistor” or “TFT” is intended to mean a field-effect transistor in which at least a channel region of the field-effect transistor is not principally a portion of a base material of a substrate. In one embodiment, the channel region of a TFT includes a-Si, polycrystalline silicon, or a combination thereof. The term “field-effect transistor” is intended to mean a transistor whose current carrying characteristics are affected by a voltage on a gate electrode. A field-effect transistor includes a junction field-effect transistor (JFET) or a metal-insulator-semiconductor field-effect transistor (MISFET), including a metal-oxide-semiconductor field-effect transistor (MOSFETs), a metal-nitride-oxide-semiconductor (MNOS) field-effect transistor, or the like. A field-effect transistor can be n-channel (n-type carriers flowing within the channel region) or p-channel (p-type carriers flowing within the channel region). A field-effect transistor may be an enhancement-mode transistor (channel region having a different conductivity type compared to the transistor's S/D regions) or depletion-mode transistor (the transistor's channel and S/D regions have the same conductivity type).

The multiplicity of electrode structure is provided on the TFT substrate. The electrodes may be anodes or cathodes. In some embodiments, the electrodes are formed as parallel strips. Alternately, the electrodes may be a patterned array of structures having plan view shapes, such as squares, rectangles, circles, triangles, ovals, and the like. Generally, the electrodes may be formed using conventional processes (e.g. deposition, patterning, or a combination thereof).

In some embodiments, the electrodes are transparent. In some embodiments, the electrodes comprise a transparent conductive material such as indium-tin-oxide (ITO). Other transparent conductive materials include, for example, indium-zinc-oxide (IZO), zinc oxide, tin oxide, zinc-tin-oxide (ZTO), elemental metals, metal alloys, and combinations thereof. In some embodiments, the electrodes are anodes for the electronic device. The electrodes can be formed using conventional techniques, such as selective deposition using a stencil mask, or blanket deposition and a conventional lithographic technique to remove portions to form the pattern. The thickness of the electrode is generally in the range of approximately 50 to 150 nm.

The photoresist is then applied to the TFT substrate with electrode structures. In some embodiments, the photoresist is applied as a liquid using liquid deposition techniques.

In some embodiments, the photoresist is positive-working, which means that the photoresist layer becomes more removable in the areas exposed to activating radiation. In some embodiments, the positive-working photoresist is a radiation-softenable composition. In this case, when exposed to radiation, the photoresist can become more soluble or dispersable in a liquid medium, more tacky, more soft, more flowable, more liftable, or more absorbable. Other physical properties may also be affected.

In some embodiments, the photoresist is negative-working, which means that the photoresist layer becomes less removable in the areas exposed to activating radiation. In some embodiments, the negative-working photoresist is a radiation-hardenable composition. In this case, when exposed to radiation, the photoresist can become less soluble or dispersable in a liquid medium, less tacky, less soft, less flowable, less liftable, or less absorbable. Other physical properties may also be affected.

Photoresist materials are well known in the art. Examples of references include Photoresist: Materials and Processes, by W. S. DeForest (McGraw-Hill, 1975) and Photoreactive Polymers: The Science and Technology of Resists, by A. Reiser (John Wiley & Sons, 1989). There are many commercially available photoresists. Examples of types of materials that can be used include, but are not limited to, photocrosslinking materials such as dichromated colloids, polyvinyl cinnamates, and diazo resins; photosolubilizing materials such as quinine diazides; and photopolymerizable materials such as vinyl ethers, epoxies, and acrylate/methacrylates. In some cases, photoreactive polyimide systems can be used.

After the photoresist is deposited and dried to form a layer, with optional baking, it is exposed to activating radiation through a gradient mask. The term “activating radiation” means energy in any form, including heat in any form, the entire electromagnetic spectrum, or subatomic particles, regardless of whether such radiation is in the form of rays, waves, or particles. In some embodiments, the activating radiation is selected from infrared radiation, visible radiation, ultraviolet radiation, and combinations thereof. In some embodiments, the activating radiation is UV radiation.

The gradient mask has a pattern in which there are areas that are transparent to the activating radiation, areas that are opaque to the activating radiation, and areas that are partially transparent (semi-transmissive) to activation radiation. In some embodiments, the partially transparent areas have 5-95% transmission; in some embodiments, 10-80% transmission; in some embodiments, 10-60% transmission; in some embodiments, 10-40% transmission; in some embodiments, 10-20% transmission.

In embodiments where a positive-working photoresist is used, the portions of the photoresist layer underneath the transparent areas of the gradient mask will become more easily removed while portions underneath the opaque areas of the mask will not be easily removed. Portions of the photoresist under the partially transparent areas of the mask will be partially removable.

In embodiments where a negative-working photoresist is used, the portions of the photoresist layer underneath the transparent areas of the gradient mask will become less removable while portions underneath the opaque areas of the mask will remain easily removed. Portions of the photoresist under the partially transparent areas of the mask will partially removable.

Exposure times and doses will depend on the composition of the photoresist used, and on the radiation source. Exemplary times and doses are well known in the photoresist art.

After exposure to activating radiation, the photoresist is developed. The term “development” and all its various forms, is intended to mean physical differentiation between areas of the photoresist exposed to radiation and areas not exposed to radiation, hereinafter referred to as “development,” can be accomplished by any known technique. Such techniques have been used extensively in the photoresist art. Examples of development techniques include, but are not limited to, treatment with a liquid medium, treatment with an absorbant material, treatment with a tacky material, and the like. In some embodiments, the photoresist is treated with a liquid medium, referred to as a developer or developer solution.

The development step results in a bank structure. The structure has openings, resulting from complete removal of the photoresist, in the pixel areas where organic active material(s) will be deposited. Surrounding each pixel opening is a bank. The structure has partially removed photoresist in the areas immediately adjacent to the pixel openings, resulting from exposure through the partially transparent areas of the mask. Further removed from the pixel openings, the structure has photoresist remaining intact.

### 3. The Second Embodiment of the Process for Forming a Backplane

In a second embodiment, there is provided an alternative process for forming a backplane for an organic electronic device, where the backplane has an inorganic bank structure. The process comprises:

providing a TFT substrate having a multiplicity of electrode structures thereon;

forming an electrically insulating inorganic layer overall

forming a photoresist layer overall;

exposing the photoresist to activating radiation through a gradient mask, the mask having a pattern of transparent areas, opaque areas, and semi-transmissive areas, such that a multiplicity of first areas of the photoresist layer are fully exposed, a multiplicity of second areas of the photoresist layer are partially exposed, and a multiplicity of third areas of the photoresist layer are not exposed;

developing the photoresist layer to form an etching mask;

treating with an etchant to remove portions of the underlying electrically insulating inorganic layer to form an inorganic bank structure.

In this embodiment, the TFT substrate and the multiplicity of electrode structures are the same as in the first embodiment. In an embodiment, the transparency to radiation of each semi-transmissive area is non-homogeneous (not uniform) in that the transparency varies across each semi-transmissive area.

After the electrode structures are formed, a layer of an electrically insulating inorganic material is applied overall. Any electrically insulating inorganic material can be used, so long as it does not detrimentally react in any subsequent processing steps. Examples of suitable materials include, but are not limited to, silicon oxides and silicon nitride. The electrically insulating inorganic layer generally has a thickness in the range of approximately 1-3 microns; in some embodiments, 1-2 microns.

After formation of the electrically insulating inorganic layer, a photoresist is applied overall. The photoresist materials and their deposition methods have been discussed above. In this embodiment, the photoresist layer must have a thickness that is sufficient to prevent etching of the underlying inorganic layer in the areas where the photoresist remains after development. In general, a thickness in the range of approximately 2.0-5.5 microns is sufficient; in some embodiments, 2.5-5.0 microns.

The photoresist layer is then exposed to actinic radiation and developed, as discussed above.

After development of the photoresist, there is an etching treatment. The etching material removes the electrically insulating inorganic layer in the areas where the photoresist has been removed. In the areas where the photoresist has been partially removed, the electrically insulating inorganic layer will be partially etched. In the areas where the photoresist remains intact, the electrically insulating inorganic layer will not be etched at all. The exact etchant to be used will depend upon the composition of the inorganic layer and such etching materials are well known. Examples of etchants include, but are not limited to, acidic materials such as HF, HF buffered with ammonium fluoride, and phosphoric acid. The etching step results in the formation of an inorganic bank structure. The structure has openings resulting from complete etching in the pixel areas where organic active material(s) will be deposited. The structure has partially removed inorganic layer in the areas immediately adjacent to the pixel openings, resulting from the partially removed photoresist. Further removed from the pixel openings, the inorganic layer remains intact.

Optionally, after the etching step, the remaining photoresist material can be stripped off. This step is also well known in the photoresist art. For positive-working photoresists, the remaining resist can be exposed to activating radiation and removed with the developer solution. Alternatively, the photoresist can be removed with solvent strippers. Negative-working photoresists can be removed by treatment with solvent strippers such as chlorinated hydrocarbons, phenols, cresols, aromatic aldehydes, and glycol ethers and esters. In some cases, the resists are removed by treatment with caustic strippers.

### 4. The Gradient Mask

The production of photoresist masks is well known in the imaging and electronic art areas. Any conventional method can be used to prepare the mask. The mask can be made of any conventional material, inorganic or organic, so long as it provides the necessary resolution and structural integrity.

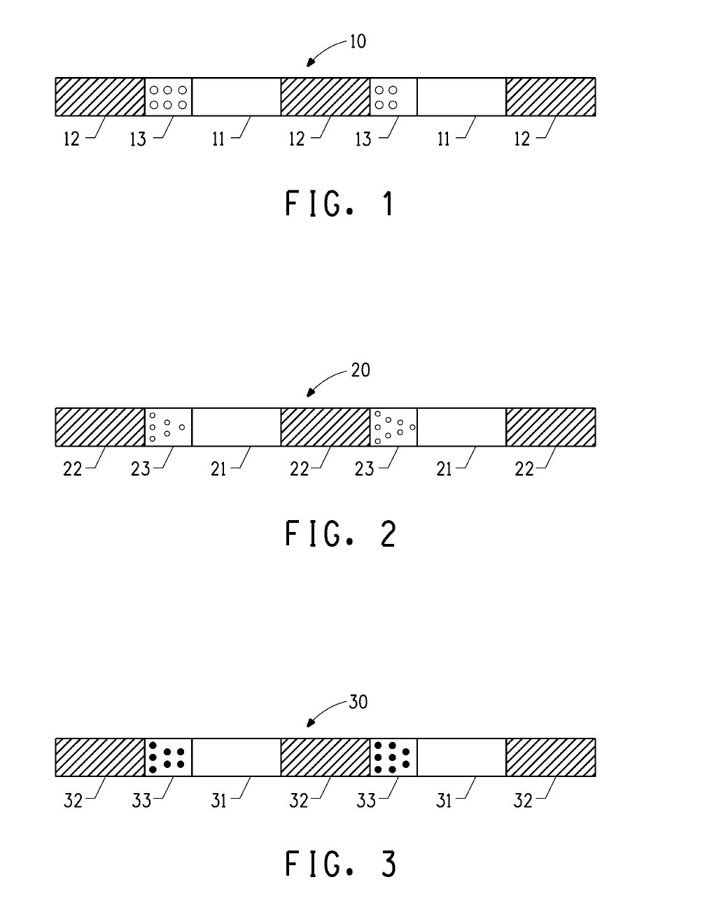

The mask is patterned to have light-transmissive areas and opaque areas, with semi-transmissive areas between them. The semi-transmissive areas can be made with a screen or mesh pattern as is known in the halftone imaging art. FIGS. 1-3 show schematic diagrams of a cross-section of some exemplary gradient masks. In FIG. 1, mask 10 has light-transmissive areas 11 and opaque areas 12. Between areas 11 and 12 are semi-transmissive areas 13. In this embodiment, the semi-transmissive areas 13 are homogeneous, having the same level of transparency throughout the area. Another embodiment of a gradient mask is shown in FIG. 2. Mask 20 has light-transmissive areas 21, opaque areas 22, and semi-transmissive areas 23. In this case, the transparency in area 23 is graduated from lower transparency adjacent area 22 to higher transparency adjacent area 21. Another embodiment of a gradient mask is show in FIG. 3. Mask 30 has light-transmissive areas 31, opaque areas 32, and semi-transmissive areas 33, where the semi-transmissive areas also have graduated transparency, using a different pattern. It will be understood that other patterns of transparency to variation in semi-transmissive areas may be used to achieve areas of graduated transparency and that the level and/or slope of the change in transparency can be different than that shown in the figures.

### 5. The Backplane and the Bank Structure

There is described herein, a new backplane for an organic electronic device. The backplane is particularly useful for forming devices by solution processing. The backplane comprises:

a TFT substrate;

a multiplicity of electrode structures;

a bank structure defining a multiplicity of pixel openings on the electrode structures;

wherein, the bank structure has a height adjacent to the pixel opening, h_{A}, and a height removed from the pixel opening, h_{R}, and h_{A} is significantly less than h_{R}. The bank structure can be either organic or inorganic.

As used herein, the term “significantly less” indicates that the value is at least 25% less, so that h_{A}≦0.75 (h_{R}). In some embodiments h_{A}≦0.50 (h_{R}). In some embodiments h_{A}≦0.10 (h_{R}).

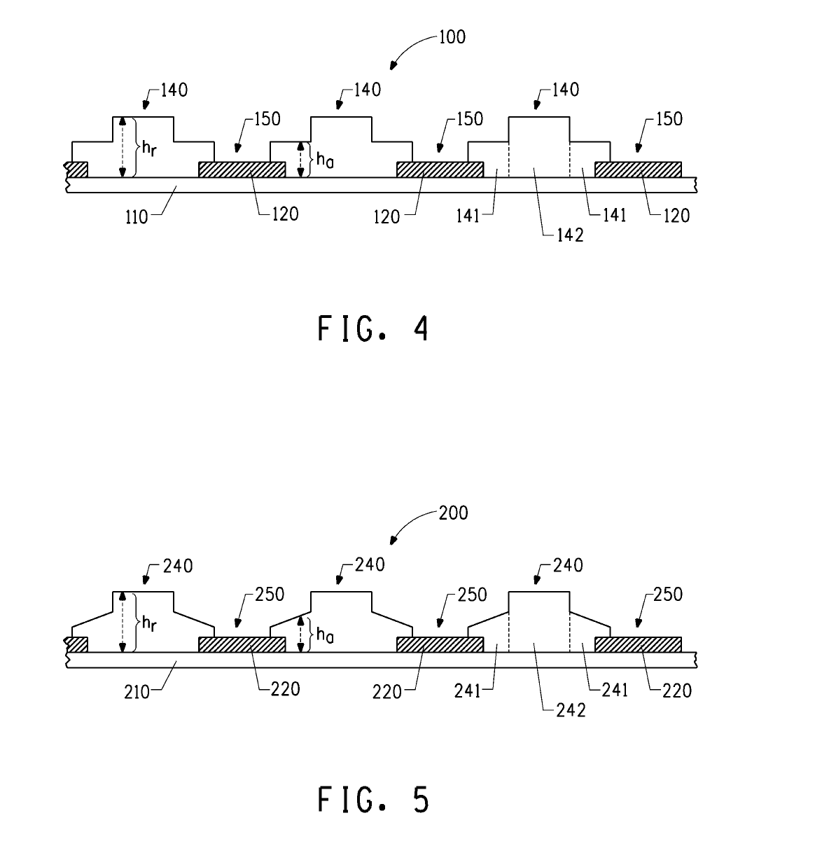

FIG. 4 gives a diagram of a cross-section of a backplane made using the mask in FIG. 1. The backplane comprises TFT substrate 110, electrodes 120, and bank structure made up of banks 140 and pixel openings 150. The banks have a portion 141 adjacent to the pixel opening and a portion 142 removed from the pixel opening. The height of the adjacent portion 141, indicated as h_{A}, is significantly less that the height of the removed portion 142, indicated as h_{R}. Since the mask in FIG. 1 has a semi-transmissive area with uniform transparency, the bank has a profile with adjacent portion 141 essentially parallel to the TFT substrate. The height h_{A} of adjacent portion 141 is taken as the distance between the upper edge of the adjacent portion and the surface of the substrate at any point of the adjacent portion.

FIG. 5 gives a diagram of a cross-section of a backplane 200 made using the mask in FIG. 2 or 3. The backplane comprises TFT substrate 210, electrodes 220, and bank structure made up of banks 240 and pixel openings 250. The banks have a portion 241 adjacent to the pixel opening and a portion 242 removed from the pixel opening. The height of the adjacent portion 241, indicated as h_{A}, is significantly less that the height of the removed portion 242, indicated as h_{R}. Since the masks in FIGS. 2 and 3 have a semi-transmissive area with graduated transparency, the bank has a profile with adjacent portion 241 starting at a higher level adjacent to the removed portion 242 and sloping to a lower level adjacent to the pixel opening. The height h_{A} of adjacent portion 241 is taken as the distance between the upper edge of the portion and the surface of the substrate at the midpoint of the adjacent portion between the removed portion and the pixel opening.

In some embodiments, the bank height h_{A} is in the range of approximately 0.5 to 3.0 microns; in some embodiments 1 to 2 microns. In some embodiments, the bank height h_{R} is in the range of approximately 100 to 5000 Å; in some embodiments, 500 to 4000 Å.

6. Process for Forming an Electronic Device

The backplane described herein is particularly suited to liquid deposition techniques for the organic active materials.

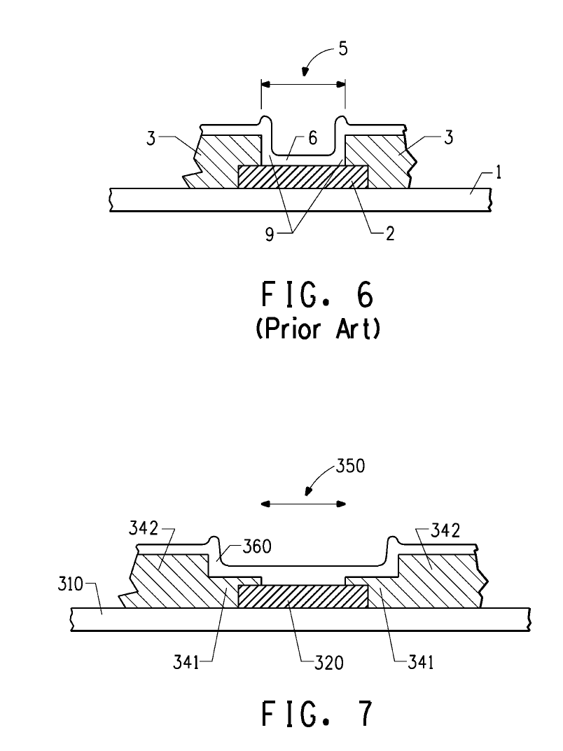

When liquid deposition techniques are used with conventional bank structures, the resulting films comprising active materials may have a non-uniform profile across the pixel opening. An example of such a non-uniform profile is shown in FIG. 6. TFT substrate 1 is shown with an electrode 2 surrounded by banks 3. The active pixel opening is illustrated as 5. When the active material is deposited as a liquid, the resulting dried film 6 does not have a uniform thickness across the entire pixel opening 5. The active film is thicker at the edges of the well, shown at 9.

FIG. 7 shows the profile of a film of active material deposited onto the new backplane described herein. TFT substrate 310 has an electrode 320 with surrounding bank structures having a portion 341 adjacent to the pixel opening and a portion 342 removed from the pixel opening. The active area of the pixel opening is illustrated as 350. The film of active material is shown as 360. Although the film 360 has some thicker areas at the outside edges of the well, the thickness in the active area of the pixel opening is substantially uniform. The advantage of forming uniform active materials in the emissive area is to provide uniform emission that will contribute to better color stability and better panel lifetime.

An exemplary process for forming an electronic device includes forming one or more organic active layers in the pixel wells of the backplane described herein using liquid deposition techniques. In some embodiments, there is one or more photoactive layers and one or more charge transport layers. A second electrode is then formed over the organic layers, usually by a vapor deposition technique. Each of the charge transport layer(s) and the photoactive layer may include one or more layers. In another embodiment, a single layer having a graded or continuously changing composition may be used instead of separate charge transport and photoactive layers.

In an exemplary embodiment, the electrode in the backplane is an anode. In some embodiments, a first organic layer comprising buffer material is applied by liquid deposition. In some embodiments, a first organic layer comprising hole transport material is applied by liquid deposition. In some embodiments, first layer comprising buffer material and a second layer comprising hole transport material are formed sequentially. After the buffer layer and/or hole transport layer are formed, a photoactive layer is formed by liquid deposition. Different photoactive compositions comprising red, green, or blue emitting-materials may be applied to different pixel areas to form a full color display. After the formation of the photoactive layer, an electron transport layer is formed by vapor deposition. After formation of the electron transport layer, an optional electron injection layer and then the cathode are formed by vapor deposition.

The term “buffer layer” or “buffer material” is intended to mean electrically conductive or semiconductive materials and may have one or more functions in an organic electronic device, including but not limited to, planarization of the underlying layer, charge transport and/or charge injection properties, scavenging of impurities such as oxygen or metal ions, and other aspects to facilitate or to improve the performance of the organic electronic device. Buffer materials may be polymers, oligomers, or small molecules, and may be in the form of solutions, dispersions, suspensions, emulsions, colloidal mixtures, or other compositions.

The buffer layer can be formed with polymeric materials, such as polyaniline (PANI) or polyethylenedioxythiophene (PEDOT), which are often doped with protonic acids. The protonic acids can be, for example, poly(styrenesulfonic acid), poly(2-acrylamido-2-methyl-1-propanesulfonic acid), and the like. The buffer layer can comprise charge transfer compounds, and the like, such as copper phthalocyanine and the tetrathiafulvalene-tetracyanoquinodimethane system (TTF-TCNQ). In one embodiment, the buffer layer is made from a dispersion of a conducting polymer and a colloid-forming polymeric acid. Such materials have been described in, for example, published U.S. patent applications 2004-0102577, 2004-0127637, and 2005/205860. The buffer layer typically has a thickness in a range of approximately 20-200 nm.

The term “hole transport,” when referring to a layer, material, member, or structure is intended to mean such layer, material, member, or structure facilitates migration of positive charge through the thickness of such layer, material, member, or structure with relative efficiency and small loss of charge. Although light-emitting materials may also have some charge transport properties, the term “charge transport layer, material, member, or structure” is not intended to include a layer, material, member, or structure whose primary function is light emission.

Examples of hole transport materials for a charge transport layer have been summarized for example, in Kirk-Othmer Encyclopedia of Chemical Technology, Fourth Edition, Vol. 18, p. 837-860, 1996, by Y. Wang. Both hole transporting molecules and polymers can be used. Commonly used hole transporting molecules include, but are not limited to: 4,4′,4″-tris(N,N-diphenyl-amino)-triphenylamine (TDATA); 4,4′,4″-tris(N-3-methylphenyl-N-phenyl-amino)-triphenylamine (MTDATA); N,N′-diphenyl-N,N′-bis(3-methylphenyl)-[1,1′-biphenyl]-4,4′-diamine (TPD); 1,1-bis[(di-4-tolylamino)phenyl]cyclohexane (TAPC); N,N′-bis(4-methylphenyl)-N,N′-bis(4-ethylphenyl)-[1,1′-(3,3′-dimethyl)biphenyl]-4,4′-diamine (ETPD); tetrakis-(3-methylphenyl)-N,N,N′,N′-2,5-phenylenediamine (PDA); α-phenyl-4-N,N-diphenylaminostyrene (TPS); p-(diethylamino)benzaldehyde diphenylhydrazone (DEH); triphenylamine (TPA); bis[4-(N,N-diethylamino)-2-methylphenyl](4-methylphenyl)methane (MPMP); 1-phenyl-3-[p-(diethylamino)styryl]-5-[p-(diethylamino)phenyl]pyrazoline (PPR or DEASP); 1,2-trans-bis(9H-carbazol-9-yl)cyclobutane (DCZB); N,N,N′,N′-tetrakis(4-methylphenyl)-(1,1′-biphenyl)-4,4′-diamine (TTB); N,N′-bis(naphthalen-1-yl)-N,N′-bis-(phenyl)benzidine (α-NPB); and porphyrinic compounds, such as copper phthalocyanine. Commonly used hole transporting polymers include, but are not limited to, polyvinylcarbazole, (phenylmethyl)polysilane, poly(dioxythiophenes), polyanilines, and polypyrroles. It is also possible to obtain hole transporting polymers by doping hole transporting molecules such as those mentioned above into polymers such as polystyrene and polycarbonate. The hole transport layer typically has a thickness in a range of approximately 40-100 nm.

“Photoactive” refers to a material that emits light when activated by an applied voltage (such as in a light emitting diode or chemical cell) or responds to radiant energy and generates a signal with or without an applied bias voltage (such as in a photodetector). Any organic electroluminescent (“EL”) material can be used in the photoactive layer, and such materials are well known in the art. The materials include, but are not limited to, small molecule organic fluorescent compounds, fluorescent and phosphorescent metal complexes, conjugated polymers, and mixtures thereof. The photoactive material can be present alone, or in admixture with one or more host materials. Examples of fluorescent compounds include, but are not limited to, naphthalene, anthracene, chrysene, pyrene, tetracene, xanthene, perylene, coumarin, rhodamine, quinacridone, rubrene, derivatives thereof, and mixtures thereof. Examples of metal complexes include, but are not limited to, metal chelated oxinoid compounds, such as tris(8-hydroxyquinolato)aluminum (Alq3); cyclometalated iridium and platinum electroluminescent compounds, such as complexes of iridium with phenylpyridine, phenylquinoline, or phenylpyrimidine ligands as disclosed in Petrov et al., U.S. Pat. No. 6,670,645 and Published PCT Applications WO 03/063555 and WO 2004/016710, and organometallic complexes described in, for example, Published PCT Applications WO 03/008424, WO 03/091688, and WO 03/040257, and mixtures thereof. Examples of conjugated polymers include, but are not limited to poly(phenylenevinylenes), polyfluorenes, poly(spirobifluorenes), polythiophenes, poly(p-phenylenes), copolymers thereof, and mixtures thereof. The photoactive layer 1912 typically has a thickness in a range of approximately 50-500 nm.

“Electron Transport” means when referring to a layer, material, member or structure, such a layer, material, member or structure that promotes or facilitates migration of negative charges through such a layer, material, member or structure into another layer, material, member or structure. Examples of electron transport materials which can be used in an optional electron transport layer, include metal chelated oxinoid compounds, such as tris(8-hydroxyquinolato)aluminum (AlQ), bis(2-methyl-8-quinolinolato)(p-phenylphenolato) aluminum (BAlq), tetrakis-(8-hydroxyquinolato)hafnium (HfQ) and tetrakis-(8-hydroxyquinolato)zirconium (ZrQ); and azole compounds such as 2-(4-biphenylyl)-5-(4-t-butylphenyl)-1,3,4-oxadiazole (PBD), 3-(4-biphenylyl)-4-phenyl-5-(4-t-butylphenyl)-1,2,4-triazole (TAZ), and 1,3,5-tri(phenyl-2-benzimidazole)benzene (TPBI); quinoxaline derivatives such as 2,3-bis(4-fluorophenyl)quinoxaline; phenanthrolines such as 4,7-diphenyl-1,10-phenanthroline (DPA) and 2,9-dimethyl-4,7-diphenyl-1,10-phenanthroline (DDPA); and mixtures thereof. The electron-transport layer typically has a thickness in a range of approximately 30-500 nm.

As used herein, the term “electron injection” when referring to a layer, material, member, or structure, is intended to mean such layer, material, member, or structure facilitates injection and migration of negative charges through the thickness of such layer, material, member, or structure with relative efficiency and small loss of charge. The optional electron-transport layer may be inorganic and comprise BaO, LiF, or Li₂O. The electron injection layer typically has a thickness in a range of approximately 20-100 Å.

The cathode can be selected from Group 1 metals (e.g., Li, Cs), the Group 2 (alkaline earth) metals, the rare earth metals including the lanthanides and the actinides. The cathode a thickness in a range of approximately 300-1000 nm.

An encapsulating layer can be formed over the array and the peripheral and remote circuitry to form a substantially complete electrical device.

Note that not all of the activities described above in the general description or the examples are required, that a portion of a specific activity may not be required, and that one or more further activities may be performed in addition to those described. Still further, the order in which activities are listed are not necessarily the order in which they are performed.

In the foregoing specification, concepts have been described with reference to specific embodiments. However, one of ordinary skill in the art appreciates that various modifications and changes can be made without departing from the scope of the invention as set forth in the claims below. Accordingly, the specification and figures are to be regarded in an illustrative rather than a restrictive sense, and all such modifications are intended to be included within the scope of the claims that follow.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims.

It is to be appreciated that certain features are, for clarity, described herein in the context of separate embodiments, may also be provided in combination in a single embodiment. Conversely, various features that are, for brevity, described in the context of a single embodiment, may also be provided separately or in any subcombination. Further, reference to values stated in ranges includes each and every value within that range.

1. A process for forming a backplane for an organic electronic device, the process comprising:
providing a TFT substrate having a multiplicity of electrode structures thereon;
forming a photoresist layer overall;
exposing the photoresist to activating radiation through a gradient mask, the mask having a pattern of transparent areas, opaque areas, and semi-transmissive areas, such that a multiplicity of first areas of the photoresist layer are fully exposed, a multiplicity of second areas of the photoresist layer are partially exposed, and a multiplicity of third areas of the photoresist layer are not exposed;
developing the photoresist layer to form an organic bank structure.

2. The process of claim 1, wherein the semi-transmissive areas of the gradient mask are homogeneous.

3. The process of claim 1, wherein the semi-transmissive areas of the gradient mask are non-homogeneous.

4. The process of claim 1, wherein the semi-transmissive areas of the gradient mask are each graduated from lower transparency adjacent the opaque areas and higher transparency adjacent the transparent areas.

5. The process of claim 1, wherein the photoresist is positive-working.

6. The process of claim 1, wherein developing is accomplished by treatment with a solvent.

7. A process for forming a backplane for an organic electronic device, the process comprising:
providing a TFT substrate having a multiplicity of electrode structures thereon;
forming an electrically insulating inorganic layer overall
forming a photoresist layer overall;
exposing the photoresist to activating radiation through a gradient mask, the mask having a pattern of transparent areas, opaque areas, and semi-transmissive areas, such that a multiplicity of first areas of the photoresist layer are fully exposed, a multiplicity of second areas of the photoresist layer are partially exposed, and a multiplicity of third areas of the photoresist layer are not exposed;
developing the photoresist layer to form an etching mask;
treating with an etchant to remove portions of the underlying electrically insulating inorganic layer to form an inorganic bank structure.

8. The process of claim 7, further comprising the step of removing the etching mask from the inorganic layer.

9. The process of claim 7 or 8, wherein the electrically insulating inorganic layer comprises a material selected from silicon oxide, silicon nitride, and combinations thereof.

10. The process of claim 7, wherein the semi-transmissive areas of the gradient mask are homogeneous.

11. The process of claim 7, wherein the semi-transmissive areas of the gradient mask are non-homogeneous.

12. The process of claim 7, wherein the semi-transmissive areas of the gradient mask are graduated from lower transparency adjacent the opaque areas and higher transparency adjacent the transparent areas.

13. The process of claim 8, wherein the photoresist is positive-working and the step of removing the etching mask is accomplished by a second exposure to activating radiating and treatment with a liquid medium.

14. (canceled)

15. (canceled)
